(19) United States
(12) Patent Application Publication
(10) Pub. No.: US 2026/0139376 A1
(43) Pub. Date: May 21, 2026

(54) SHOWERHEAD FOR DIFFUSION BONDED, MULTI-ZONE GAS DISPERSION

(71) Applicant: LAM RESEARCH CORPORATION, Fremont, CA (US)

(72) Inventors: Gary B. LIND, Penn Valley, CA (US); Anand CHANDRASHEKAR, Fremont, CA (US); Sean M. DONNELLY, Portland, OR (US); Leonard KHO, San Francisco, CA (US); Atul Kumar GARG, Banda Belai (IN); Arun Kumar HOSUR SHIVALINGE GOWDA, Bangalore (IN)

(21) Appl. No.: 19/117,158

(22) PCT Filed: Sep. 27, 2023
(86) PCT No.: PCT/US2023/033786

§ 371 Date: Mar. 31, 2025

Related U.S. Application Data
(60) Provisional application No. 63/413,846, filed on Oct. 6, 2022.

(51) Int. Cl. C23C 16/455; C23C 16/458

(52) U.S. Cl. CPC C23C 16/45565; C23C 16/45544; C23C 16/4583

(57) ABSTRACT

A showerhead for a substrate processing chamber configured to perform bulk deposition includes a faceplate, a backplate, and a faceplate. The faceplate defines a first plenum corresponding to center and middles zones and a second plenum corresponding to an edge zone. The faceplate includes a first plurality of holes distributed throughout the center zone and the middle zone and a second plurality of holes distributed throughout the edge zone. The middle plate is disposed between the faceplate and the backplate. The faceplate is configured to receive a first gas mixture supplied to the center zone via a center inlet, receive a second gas mixture supplied to the middle zone via a middle inlet, blend the first gas mixture and the second gas mixture within the first plenum, and receive a third gas mixture supplied to the edge zone via an edge inlet.

### CROSS-REFERENCE TO RELATED APPLICATIONS

This application claims the benefit of U.S. Provisional Application No. 63/413,846, filed on Oct. 6, 2022. The entire disclosure of the application referenced above is incorporated herein by reference.

### FIELD

The present disclosure relates to showerhead, pedestal, and chamber designs for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically comprises a plurality of stations in which to perform deposition, etching, and other treatments on substrates such as semiconductor wafers. Examples of processes that may be performed on a substrate comprise a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, the substrate is disposed in the processing chamber on a substrate support such as an electrostatic chuck (ESC) or a pedestal. Process gases are introduced and, in some examples, plasma is struck in the processing chamber. The process gases are introduced using a gas distribution device, such as a showerhead.

### SUMMARY

A showerhead for a substrate processing chamber configured to perform bulk deposition on a substrate includes a faceplate, a backplate, and a faceplate. The faceplate defines at least a first plenum and a second plenum, the first plenum corresponding to a center zone of the faceplate and a middle zone of the faceplate located radially outside of the center zone and the second plenum corresponding to an edge zone located radially outside of the middle zone. The faceplate includes a first plurality of holes distributed throughout the center zone and the middle zone and a second plurality of holes distributed throughout the edge zone. The second plenum is not in fluid communication with the first plenum. The middle plate is disposed between the faceplate and the backplate. The faceplate is configured to receive a first gas mixture supplied to the center zone via a center inlet, receive a second gas mixture supplied to the middle zone via a middle inlet, blend the first gas mixture and the second gas mixture within the first plenum, and receive a third gas mixture supplied to the edge zone via an edge inlet.

In other features, the faceplate, the middle plate, and the backplate are diffusion bonded together. The first plenum is not in fluid communication with the second plenum. The showerhead further includes a stem and the first gas mixture is supplied to the center zone via a first flow path through the stem. The second gas mixture is supplied to the middle zone via a second flow path through the stem, the backplate, and the middle plate. The third gas mixture is supplied to the edge zone via a third flow path through the stem, the backplate, and the middle plate. The backplate comprises a third plenum, and wherein the third gas mixture is supplied to the third plenum and to the second plenum from the third plenum via the edge inlet. The middle plate comprises a fourth plenum, and wherein the second gas mixture is supplied to the fourth plenum and to the first plenum from the fourth plenum via the middle inlet.

In other features, the showerhead further includes a plurality of first posts defined within the first plenum. The plurality of first posts is configured to facilitate blending of the first gas mixture and the second gas mixture within the first plenum. The showerhead further includes a plurality of second posts defined within the first plenum. The plurality of second posts is configured to facilitate heat transfer from the faceplate to the middle plate. The posts of the plurality of second posts have a greater height than the posts of the plurality of first posts. The posts of the plurality of second posts have a greater diameter than the posts of the plurality of first posts. The plurality of first posts and the plurality of second posts extend downward from a lower surface of the middle plate into the first plenum.

In other features, openings of the holes of the first plurality of holes and the second plurality of holes on a lower surface of the faceplate are conical. The openings of the holes flare outward at an angle between 40 and 60 degrees. A substrate processing chamber includes the showerhead and further includes a pedestal configured to support the substrate. A gap between the faceplate and the pedestal is between 0.125 and 0.750 inches (3.175 and 19.05 mm).

A substrate processing chamber configured to perform bulk deposition on a substrate subsequent to nucleation of the substrate includes a showerhead comprising a head portion and a stem portion, the head portion defining at least a first plenum and a second plenum, the first plenum corresponding to a center zone and a middle zone located radially outside of the center zone and the second plenum corresponding to an edge zone located radially outside of the middle zone. The head portion includes a first plurality of holes distributed throughout the center zone and the middle zone and a second plurality of holes distributed throughout the edge zone. The second plenum is not in fluid communication with the first plenum. The showerhead is configured to receive a first gas mixture supplied to the center zone via a center inlet, receive a second gas mixture supplied to the middle zone via a middle inlet, blend the first gas mixture and the second gas mixture within the first plenum, and receive a third gas mixture supplied to the edge zone via an edge inlet. A pedestal is configured to support the substrate. A gap between a lower surface of the head portion and the pedestal is between 0.125 and 0.750 inches (3.175 and 19.05 mm).

In other features, a system includes the substrate processing chamber and further includes a gas delivery system configured to independently supply respective gases of a plurality of gases to the center zone, the middle zone, and the edge zone. Openings of the holes of the first plurality of holes and the second plurality of holes on a lower surface of the head portion are conical. The head portion of the showerhead comprises a faceplate, a middle plate, and a backplate diffusion bonded together.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system comprising an example carrier ring according to the present disclosure;

FIG. 2 shows an example processing chamber, showerhead, and substrate support according to the present disclosure; and

FIG. 3A shows an example plenum according to the present disclosure;

FIG. 3B shows an example surface of a plate of a showerhead according to the present disclosure; and

FIG. 4 illustrates steps of an example method of performing a deposition process according to the present disclosure.

In the drawings, reference numbers may be reused to identify similar and/or identical elements.

### DETAILED DESCRIPTION

A substrate processing tool comprises one or more process modules or chambers. For example, a multi-station module (e.g., a quad-station module (QSM)) comprises a plurality of stations in which to perform deposition, etching, and other treatments on substrates. Different processes may be performed in respective stations. Conversely, a single station module comprises only a single station.

In some examples, a nucleation process (e.g., an atomic layer deposition (ALD) nucleation step) is performed in a first station of a multi-station module while bulk fill/deposition steps are performed in other stations of the multi-station module. Optimal chamber dimensions and geometry and/or process parameters may differ for respective steps. For example, optimal chamber pressure and temperature for the nucleation step may be lower than optimal chamber pressure and temperature for bulk deposition steps. However, since the stations in a multi-station module share the same processing chamber, processing chamber conditions may not be optimal for either nucleation or bulk deposition steps.

A process module according to the present disclosure comprises components optimized for bulk deposition steps of an ALD process. For example, the process module is a single station module configured to perform bulk deposition steps separately from a nucleation step. The nucleation step may be performed in a different module or tool prior to being transferred to the process module. Accordingly, nucleation and bulk deposition steps can be performed in respective optimal process conditions. Although described with respect to bulk deposition, the principles of the present disclosure may also be applied to other types of deposition.

The process module comprises a showerhead configured to perform bulk deposition. For example, the showerhead is configured to provide multi-zone gas dispersion with radial film profile tunability. In an example, the showerhead has a diffusion bonded construction providing a high thermal load with integral passages defined in three separate zones (e.g., a center zone, a radial or middle zone, and an outer or edge zone). Each zone can be controlled to either add or delete reactants supplied to different regions of the substrate to tune deposition rates and film properties in the different regions of the substrate.

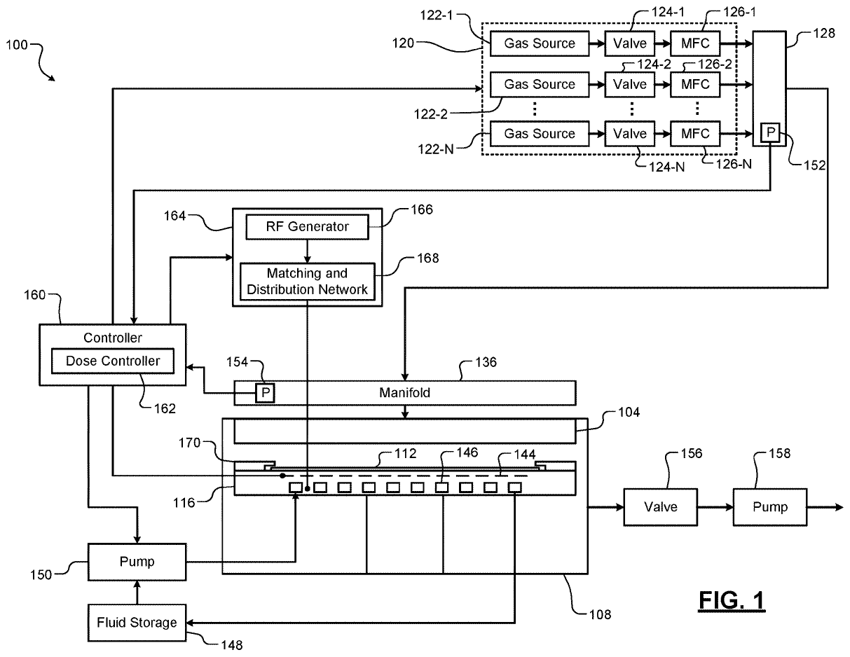

Referring now to FIG. 1, an example of a substrate processing system 100 comprising a showerhead 104 according to the present disclosure is shown. The showerhead 104 is arranged within an upper surface or portion of a processing chamber 108. A substrate 112 is arranged on a substrate support 116 (e.g., a pedestal configured for CVD and/or ALD deposition) during processing. For example, bulk deposition of an ALD process is performed on the substrate 112.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied to a manifold 136. An output of the manifold 136 is input the showerhead 104 (e.g., a multi-injector, multi-zone showerhead as described below in more detail). While the manifolds 128 and 136 are shown, a single manifold can be used.

In some examples, a temperature of the substrate support 116 may be controlled using resistive heaters 144. The substrate support 116 may comprise coolant channels 146. Cooling fluid is supplied to the coolant channels 146 from a fluid storage 148 and a pump 150. Pressure sensors 152, 154 may be arranged in the manifold 128 or the manifold 136, respectively, to measure pressure. A valve 156 and a pump 158 may be used to evacuate reactants from the processing chamber 108 and/or to control pressure within the processing chamber 108.

A controller 160 comprises a dose controller 162 that controls dosing provided by the showerhead 104. The controller 160 also controls gas delivery from the gas delivery system 120. The controller 160 controls pressure in the processing chamber and/or evacuation of reactants using the valve 156 and the pump 158. The controller 160 controls the temperature of the substrate support 116 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 108 as deposition processes. Accordingly, the substrate processing system 100 may comprise an RF generating system 164 configured to generate and provide RF power (e.g., as a voltage source, current source, etc.) to one of a lower electrode (e.g., a baseplate of the substrate support 116, as shown) and an upper electrode (e.g., the showerhead 104). The other one of the lower electrode and the upper electrode may be DC grounded, AC grounded or floating.

For example only, the RF generating system 164 may comprise an RF generator 166 configured to generate the RF voltage that is fed by a matching and distribution network 168 to generate plasma within the processing chamber 108 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only, transformer coupled plasma (TCP) systems, CCP cathode systems, remote microwave plasma generation and delivery systems, etc.

The substrate support 116 comprises a carrier ring 170. In some examples, an inner edge of the carrier ring 170 overlaps an outer edge of the substrate 112. In some examples, the substrate support 116 is lowered for transfer of the substrate 112 into the processing chamber 108. For example, the substrate 112 is transferred onto lift pins (not shown) that are exposed when the substrate support 116 is lowered. The substrate support 116 is then raised to engage the substrate 112 and the carrier ring 170.

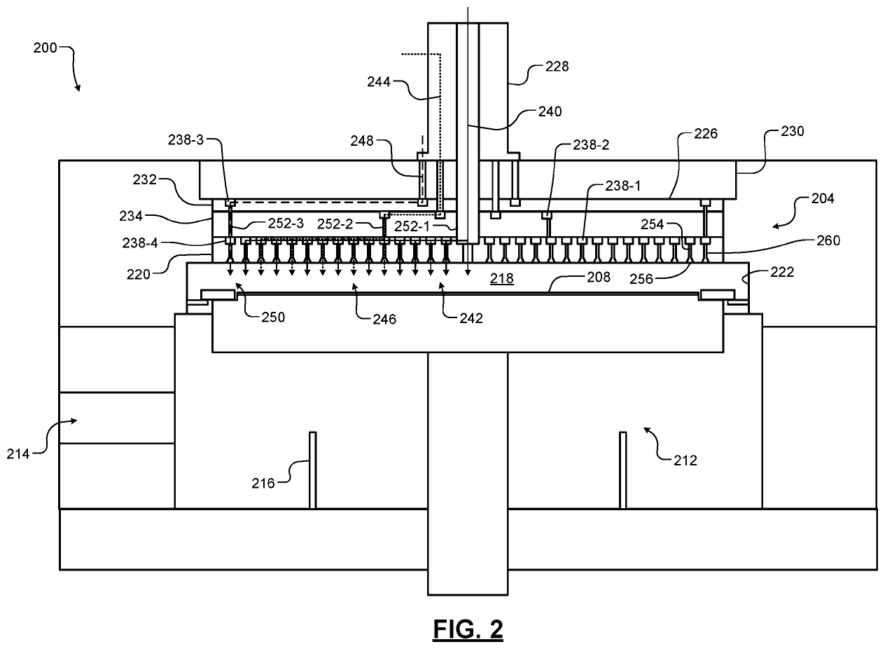

FIG. 2 shows an example processing chamber 200 comprising a showerhead 204 according to the present disclosure. In an example, the processing chamber 200 corresponds to a station of a single station module. The processing chamber 200 is configured to perform a bulk deposition step on a substrate 208 subsequent to a nucleation step performed in a different processing chamber. For example, subsequent to a nucleation step, the substrate 208 is transferred to a substrate support (e.g., a pedestal) 212 arranged within the processing chamber 200.

In one example, the substrate 208 is transferred through a slot or other opening 214 in a sidewall of the processing chamber 200 when the pedestal 212 is in a lowered position. When the pedestal 212 is in the lowered position, lift pins 216 extend above an upper surface of the pedestal 212 and the substrate 208 is placed onto the lift pins 216 (e.g., using a transfer robot). The pedestal 212 is then raised to lift and support the substate 208 in a raised position as shown in FIG. 2.

Each of the processing chamber 200, the showerhead 204, and the pedestal 212 is configured to minimize azimuthal non-symmetries in a deposition zone 218 defined between the showerhead 204 and the pedestal 212. For example, the deposition zone 218 is a symmetrically annular volume defined between a lower, substrate-facing faceplate 220 of the showerhead 204, an annular inner surface 222 of the processing chamber 200, and the pedestal 212. Further, a gap between the faceplate 220 and the pedestal 212 is minimized to maintain uniformity of process gas flow and distribution within the deposition zone 218. For example, a width of the gap between faceplate 220 and the pedestal 212 is between 0.125 and 0.750 inches (3.175 and 19.05 mm).

The showerhead 204 is comprised of a base or head portion 226 and a stem portion 228. The stem portion 228 extends through an upper wall (e.g., a lid 230) of the processing chamber 200 to connect to the head portion 226. For example, the head portion 226 comprises the faceplate 220, a backplate 232, and a middle plate 234 disposed between the faceplate 220 and the backplate 232. In this example, the faceplate 220 functions as an upper surface of the processing chamber 200.

Accordingly, the head portion 226 is comprised of multiple portions coupled together. In an example, the faceplate 220, the backplate 232, and the middle plate 234 are diffusion bonded together. In an example, the showerhead has a diffusion bonded, high solidity construction that provides a high thermal load and facilitates temperature uniformity as described below in more detail.

The faceplate 220, the backplate 232, and the middle plate 234 define at least three flow paths and respective plenums 238 within the head portion 226 to provide radial tunability and process configurability. For example, one or more plenums 238-1 are defined in an upper surface of the faceplate 220, a plenum 238-2 is defined in an upper surface of the middle plate 234, a plenum 238-3 is defined in an upper surface of the backplate 232, and a plenum 238-4 is defined in the faceplate 220 radially outside of the plenum 238-1. The plenums 238-1, 238-2, 238-3, and 238-4 are referred to collectively as plenums 238.

As shown, a first flow path (shown as solid lines/arrows) 240 supplies gases through the stem 228 and into a corresponding plenum defined in a center zone 242 of the faceplate 220. A second flow path (shown as dotted lines/arrows) 244 supplies gases through the stem 228 and into a corresponding plenum defined in a radial or middle zone 246 of the faceplate 220. A third flow path (shown as dashed lines/arrows) 248 supplies gases through the stem 228 and into a corresponding plenum defined in an outer or edge zone 250 of the faceplate 220. For example only, the first flow path 240 is routed through the stem 228 to supply gases to the center zone 242 via a center inlet 252-1, the second flow path 244 is routed through the backplate 232 and the middle plate 234 to supply gases to the middle zone 246 through a middle inlet 252-2, and the third flow path 248 is routed through the backplate 232 and the middle plate 234 to supply gases to the edge zone 250 through an edge inlet 252-3.

The faceplate 220 includes a plurality of holes 254 extending from the plenums 238 to the deposition zone 218 within the processing chamber 200. For example, gases in the first flow path 240 flow through holes 254 in the center zone 242, gases in the second flow path 244 flow through holes 254 in the middle zone 246, and gases in the third flow path 248 flow through holes 254 in the edge zone 250. In some examples, bottom portions or openings 256 of the holes 254 are cone-shaped to allow gases exiting the holes 254 to flare outward. For example, the openings 256 flare outward at an angle between 40 and 60 degrees. In this manner, coverage of each of the holes 254 is widened to compensate for the decreased gap between the faceplate 220 and the substrate 208.

Gases supplied to the center zone 242, the middle zone 246, and the edge zone 250 can be independently controlled to either add or delete specific reactants (i.e., gases) supplied to corresponding regions of the substrate 208. For example, a gas mixture supplied to the deposition zone 218 to perform bulk deposition may include various reactive and non-reactive gases, such as argon (Ar), molecular hydrogen (H₂), tungsten hexafluoride (WF₆), molecular nitrogen (N₂), etc. Other gases and gas mixtures may be supplied in other examples, such as diborane (C₂H₆), silane (SiH₄), etc. Amounts of each of the gases supplied to the respective zones 242, 246, 250 can be controlled (e.g., using separately controllable components of a gas control system, such as the gas control system 120) to tune deposition rates and film properties in the different regions of the substrate 208. In other words, amounts of each gas supplied to each of the zones can be independently controlled.

For example, to increase a deposition rate, an amount of a reactant gas (e.g., WF₆) supplied to a selected zone can be increased and/or an amount of a dilutant gas (e.g., Ar) can be decreased. Conversely, to decrease a deposition rate, an amount of the reactant gas supplied to a selected zone can be decreased and/or an amount of a dilutant gas can be increased.

As shown in FIG. 2, gases provided to the edge zone 250 via the third flow path 248 are provided only to outermost holes 260 in the faceplate 220. In other words, the third flow path 248 does not supply gases to the center zone 242 and the middle zone 246. For example, the holes 260 are in fluid communication with the plenum 238-3 and the plenum 238-4 defined in the edge zone 250 of the faceplate 220 but are not in fluid communication with the plenum 238-1 defined in the center zone 242 and the middle zone 246. As an example, the plenum 238-4 in the edge zone 250 is separated from the plenum 238-1 in the center zone 242 and the middle zone 246.

Conversely, the plenum 238-1 may correspond to a single plenum defined in both the center zone 242 and the middle zone 246. Accordingly, gases supplied via both the first flow path 240 and the second flow path 244 are supplied to the same plenum 238-1. The gases supplied via the first flow path 240 and the second flow path 244 are blended within the plenum 238-1 and flow through the holes 254.

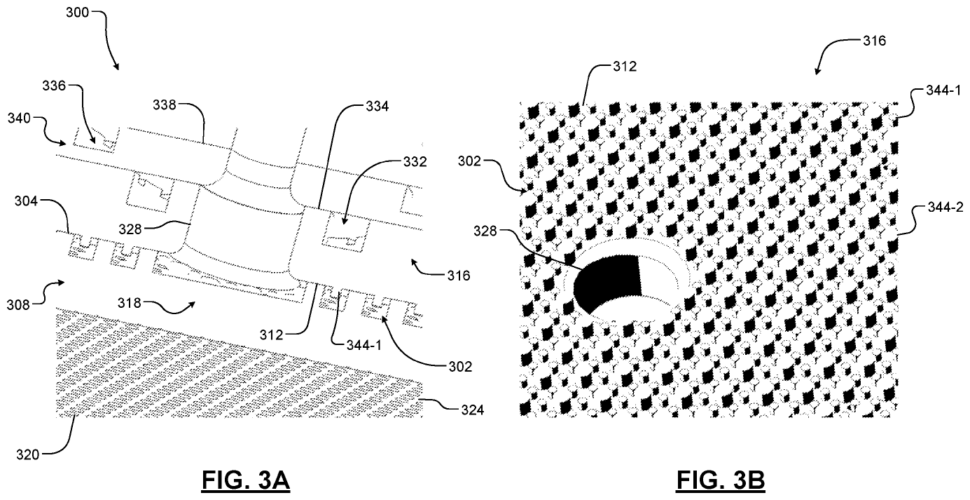

Referring now to FIGS. 3A and 3B and with continued reference to FIG. 2, an example showerhead 300 comprising a plenum 302 defined between an upper surface 304 of a faceplate 308 and a bottom or lower surface 312 of a middle plate 316 is shown. FIG. 3A shows a center region or zone 318 of the showerhead 300 and FIG. 3B shows the lower surface 312 of the middle plate 316.

As shown in FIG. 3A, the faceplate 308 includes a plurality of holes 320 extending from the plenum 302 to a bottom or lower surface 324 of the faceplate 308. The plenum 302 and the holes 320 are in fluid communication with a center inlet 328 of the showerhead 300. Conversely, a plenum 332 is defined in an upper surface 334 of the middle plate 316. The plenum 332 is in fluid communication with holes 320 and portions of the plenum 302 radially outside of the center zone 318 (not shown in FIG. 3A). A plenum 336 (corresponding to the plenum 238-3) is defined in an upper surface 338 of a backplate 340.

A plurality of posts 344 extend downward from the lower surface 312 of the middle plate 316 into the plenum 302. The posts 344 include first posts 344-1 and second posts 344-2, referred to collectively as the posts 344. A height of the second posts 344-2 is greater than a height of the first posts 344-1. Accordingly, the second posts 344-2 are taller than the first posts 344-1 and extend closer to the upper surface 304 of the faceplate 308 than the first posts 344-1. In some examples, the second posts have a greater diameter than the first posts. In some examples, the second posts 344-2 contact the upper surface 304 of the faceplate 308 within the plenum 302.

In this manner, the second posts 344-2 increase the solidity of the showerhead 300 and provide thermally conductive paths between the faceplate 308 and the middle plate 316. In other words, the second posts 344-2 decrease the overall volume of the plenum 302 and increase the surface area within the plenum 302. Accordingly, temperature uniformity of the faceplate 308 is increased.

Conversely, the first posts 344-1 cause turbulent flow of gas mixtures within the plenum 302. For example, the first posts 344-1 prevent gases from flowing throughout the plenum 302 in direct paths. Instead, the first posts 344-1 interrupt and redirect gas flow to facilitate mixing of different gases. Accordingly, a gas mixture flowing though the holes 320 includes a more uniform mixture of gases supplied to the plenum 302. For example, the first posts 344-1 facilitate blending of the gases separately supplied to the plenum 344-1 via different flow paths (e.g., the first flow path 240 and the second flow path 244).

A pattern of the first posts 344-1 may be selected to provide a desired amount of turbulence and flow of gases within the plenum 302. In one example, the first posts 344-1 are arranged in hexagonal patterns around respective ones of the second posts 344-2. In another example, the first posts 344-1 are arranged in a Vogel or other spiral pattern.

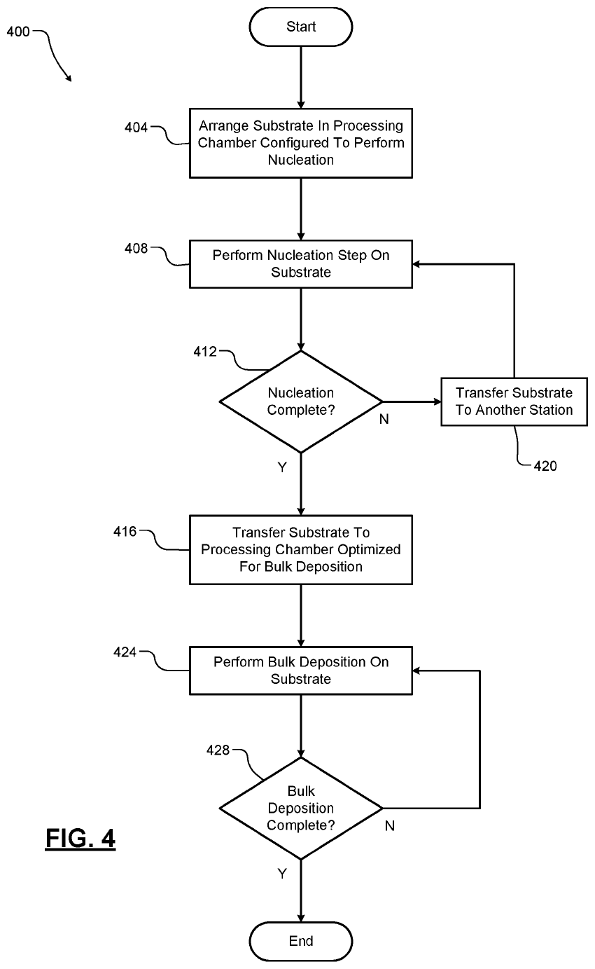

FIG. 4 illustrates steps of an example method 400 of performing a deposition process according to the present disclosure. For example, the deposition process is an ALD process performed in one or more processing chambers using a controller 160, a gas delivery system 120, etc. as shown in FIG. 1. In an embodiment, nucleation steps are performed on a substrate arranged in a first processing chamber or station optimized specifically for nucleation steps. Subsequent to nucleation steps, the substrate is transferred to a second processing chamber or station optimized for bulk deposition steps. For example, the second processing chamber is a single station module configured to minimize azimuthal non-symmetries in bulk deposition steps, such as the processing chamber 200 described above in FIG. 2.

At 404, the substrate is arranged at a first station in a processing chamber configured to perform nucleation (e.g., a nucleation processing chamber). In some examples, the first station is a station in a quad station module. At 408, a first nucleation step is performed on the substrate. At 412, the method 400 (e.g., the controller 160) determines whether nucleation is complete. For example, in embodiments, multiple nucleation steps can be performed on the same substrate at different stations in a multi-station module. If true, the method 400 continues to 416. If false, the method 400 continues to 420. At 420, the substrate is transferred to another station (e.g., a second station, a third station, a fourth station, etc.) in the multi-station module for another nucleation step.

When nucleation is complete, at 416 the substrate is transferred out of the nucleation processing chamber and into a station in a processing chamber optimized for bulk deposition (e.g., a bulk deposition processing chamber). In an embodiment, the bulk deposition processing chamber is a single station module. At 424, bulk deposition is performed on the substrate. As described above in FIG. 2, performing bulk deposition according to the present disclosure includes individually adjusting flow rates of gases in multiple zones of a showerhead to add reactant gases to or delete reactant gases from specific regions of a deposition zone above the substrate. In this manner, deposition uniformity can be improved. In some examples, deposition non-uniformity can be intentionally introduced to achieved different deposition thicknesses in different regions of the substrate (e.g., to compensate for non-uniformities in prior and/or subsequent steps, to compensate for other process non-uniformities, etc.).

At 428, the method 400 (e.g., the controller 160) determines whether bulk deposition is complete. For example, the method 400 determines whether a target deposition or accumulation amount is achieved. If true, the method 400 ends. If false, the method 400 continues bulk deposition at 424.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a substrate processing chamber configured to perform bulk deposition on a substrate, the showerhead comprising:
a faceplate defining at least a first plenum and a second plenum, the first plenum corresponding to a center zone of the faceplate and a middle zone of the faceplate located radially outside of the center zone and the second plenum corresponding to an edge zone located radially outside of the middle zone, wherein the faceplate includes a first plurality of holes distributed throughout the center zone and the middle zone and a second plurality of holes distributed throughout the edge zone, and wherein the second plenum is not in fluid communication with the first plenum;
a middle plate; and
a backplate, wherein the middle plate is disposed between the faceplate and the backplate, and wherein
the faceplate is configured to (i) receive a first gas mixture supplied to the center zone via a center inlet, (ii) receive a second gas mixture supplied to the middle zone via a middle inlet, (iii) blend the first gas mixture and the second gas mixture within the first plenum, and (iv) receive a third gas mixture supplied to the edge zone via an edge inlet.

2. The showerhead of claim 1, wherein the faceplate, the middle plate, and the backplate are diffusion bonded together.

3. The showerhead of claim 1, wherein the first plenum is not in fluid communication with the second plenum.

4. The showerhead of claim 1, further comprising a stem, wherein the first gas mixture is supplied to the center zone via a first flow path through the stem.

5. The showerhead of claim 4, wherein the second gas mixture is supplied to the middle zone via a second flow path through the stem, the backplate, and the middle plate.

6. The showerhead of claim 5, wherein the third gas mixture is supplied to the edge zone via a third flow path through the stem, the backplate, and the middle plate.

7. The showerhead of claim 6, wherein the backplate comprises a third plenum, and wherein the third gas mixture is supplied (i) to the third plenum and (ii) to the second plenum from the third plenum via the edge inlet.

8. The showerhead of claim 7, wherein the middle plate comprises a fourth plenum, and wherein the second gas mixture is supplied (i) to the fourth plenum and (ii) to the first plenum from the fourth plenum via the middle inlet.

9. The showerhead of claim 1, further comprising a plurality of first posts defined within the first plenum, wherein the plurality of first posts is configured to facilitate blending of the first gas mixture and the second gas mixture within the first plenum.

10. The showerhead of claim 9, further comprising a plurality of second posts defined within the first plenum, wherein the plurality of second posts is configured to facilitate heat transfer from the faceplate to the middle plate.

11. The showerhead of claim 10, wherein the posts of the plurality of second posts have a greater height than the posts of the plurality of first posts.

12. The showerhead of claim 11, wherein the posts of the plurality of second posts have a greater diameter than the posts of the plurality of first posts.

13. The showerhead of claim 9, wherein the plurality of first posts and the plurality of second posts extend downward from a lower surface of the middle plate into the first plenum.

14. The showerhead of claim 1, wherein openings of the holes of the first plurality of holes and the second plurality of holes on a lower surface of the faceplate are conical.

15. The showerhead of claim 14, wherein the openings of the holes flare outward at an angle between 40 and 60 degrees.

16. A substrate processing chamber comprising the showerhead of claim 1 and further comprising a pedestal configured to support the substrate, wherein a gap between the faceplate and the pedestal is between 0.125 and 0.750 inches (3.175 and 19.05 mm).

17. A substrate processing chamber configured to perform bulk deposition on a substrate subsequent to nucleation of the substrate, the substrate processing chamber comprising:
a showerhead comprising a head portion and a stem portion, the head portion defining at least a first plenum and a second plenum, the first plenum corresponding to a center zone and a middle zone located radially outside of the center zone and the second plenum corresponding to an edge zone located radially outside of the middle zone, wherein the head portion includes a first plurality of holes distributed throughout the center zone and the middle zone and a second plurality of holes distributed throughout the edge zone, and wherein the second plenum is not in fluid communication with the first plenum, wherein
the showerhead is configured to (i) receive a first gas mixture supplied to the center zone via a center inlet, (ii) receive a second gas mixture supplied to the middle zone via a middle inlet, (iii) blend the first gas mixture and the second gas mixture within the first plenum, and (iv) receive a third gas mixture supplied to the edge zone via an edge inlet; and
a pedestal configured to support the substrate, wherein a gap between a lower surface of the head portion and the pedestal is between 0.125 and 0.750 inches (3.175 and 19.05 mm).

18. A system comprising the substrate processing chamber of claim 17 and further comprising a gas delivery system configured to independently supply respective gases of a plurality of gases to the center zone, the middle zone, and the edge zone.

19. The substrate processing chamber of claim 17, wherein openings of the holes of the first plurality of holes and the second plurality of holes on a lower surface of the head portion are conical.

20. The substrate processing chamber of claim 17, wherein the head portion of the showerhead comprises a faceplate, a middle plate, and a backplate diffusion bonded together.
